(19) United States
(12) Patent Application Publication
(10) Pub. No.: US 2024/0250495 A1
(43) Pub. Date: Jul. 25, 2024

(54) Method And Apparatus For A Fast Axis Laser Line

(71) Applicant: Richard Redpath, Cary, NC (US)

(72) Inventor: Richard Redpath, Cary, NC (US)

(21) Appl. No.: 17/004,536

(22) Filed: Aug. 27, 2020

(51) Int. Cl. G02B 27/09; G02B 27/42

(52) U.S. Cl. CPC G02B 27/0916; G02B 27/0955; G02B 27/4233

(57) ABSTRACT

The apparatus is designed to provide a laser line from a fast/slow axis laser that varies in ratio with bin lot production and or temperature. The invention is designed to have a laser line that is intended to be used in varying temperature environments and binning of laser diodes that vary in fast/slow axis for fire rescue.

The current application claims a priority to the U.S. Provisional Patent application Ser. No. 62/894,986 filed on Sep. 3, 2019.

### FIELD OF THE INVENTION

The present invention relates generally to a laser line projection, more particularly an apparatus that uses laser diode for laser light having an intrinsic fast/slow axis that changes in ratio with bin lot and or temperature to produce an optimal laser line for fire rescue. A user of the present invention will be able to manufacture an apparatus that uses a fast/slow axis laser beam that is focused to produce a laser line for varying fast/slow axis ratios in a bin lot for laser diodes and address temperature changes for its operational environment in fire rescue.

### BACKGROUND OF THE INVENTION

A laser beam can produce a laser line using a Powell lens, a Cylindrical Lens Array, or a Diffraction Optical Element (DOE) to control the fan angle and intensity distribution along the length of the line. Typical laser diodes have a fast/slow axis and an aspherical lens is used to shape the laser beam to be round. This round beam is then processed by a Powell lens, a Cylindrical Lens Array, or a Diffraction Optical Element (DOE) to produce a laser line. As the beam diverges the line naturally gets thicker due to this fast/slow axis limitation of the spherical lens as well as the divergence factor of the laser light. The issue at hand is that a laser diode has a range of fast/slow axis ratio for bin lot production and for different temperatures when operated. A fixed aspherical lens can be focused to adjust the laser beam output to be round for a specific temperature and expected typical fast/slow axis ratio but if the temperature changes the beam becomes more elliptical and hence the line becomes more thick and less sharp requiring an adjustment of the fixed aspherical lens focus.

Imperfections in the produced laser line becomes an issue if you are operating a laser line in fire rescue environments where temperature is changing of which the fast/slow axis of the laser changes. In addition, laser diodes have a bin lot range min/max and typical for fast/slow axis of which an aspherical lens is designed for the typical measure to produce a round laser beam. When the laser beam is focused using a Powell lens, a Cylindrical Lens Array, or a Diffraction Optical Element (DOE) into a line that line can vary in thickness depending on laser diode lot for its min/max and typical specification. Most importantly if the typical fast/slow axis ratio is used for the aspherical lens specifications selected laser diodes that are bin lot productions outside of this typical range will produce less quality of a line verses others that meet the typical range.

Therefore, the object of the present invention is a seamless solution to provide a laser line that is aligned to the fast axis of the laser to produce a laser line for varying temperatures and bin lot of production of the laser diode. The present invention is to provide a method and apparatus for a laser line from a laser diode that has a fast/slow axis that can change with temperature or bin lot production to operate optimally for a laser line for fire rescue. For reference U.S. Pat. No. 8,672,513 describes using a laser line apparatus for fire rescue. Furthermore, a single spherical lens can be chosen that can source the laser diode as a varying elliptical beam for bin lot production that will provide a same quality line that does not change for bin lot laser diode production.

### BRIEF DESCRIPTION OF THE DRAWINGS

FIG. 1 is a diagram illustrating the invention to align the fast axis of the laser to the laser line lens system.

### DETAIL DESCRIPTIONS OF THE INVENTION

All illustrations of the drawings are for the purpose of describing selected versions of the present invention and are not intended to limit the scope of the present invention.

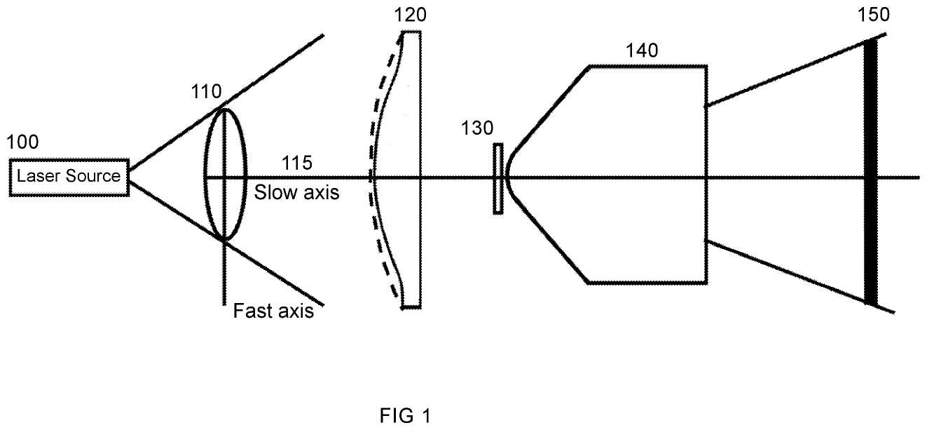

Referring to FIG. 1 at 100 is a laser light source projection shown as output with a diagram of the fast and slow axis at 110 along the projection line at 115. At 120 is a lens to focus the laser light source as a beam with a fast/slow axis characteristic. The beam impacting at 130 will be an ellipse line shape. At 130 is diagramed the laser beam shape that is essentially an elliptical line due to the fast axis, incidences a Powell lens at 140 with the fast axis perpendicular to the Powell cone shape shown at 130. The Powell lens produces a line at 150 with an intrinsic fan angle.

Although the invention has been explained in relation to its preferred embodiment, it is to be understood that many other possible modifications and variations can be made without departing from the spirit and scope of the invention.

What is claimed is:

1. A method and apparatus for a laser line aligned to the fast axis of the laser source for fire rescue wherein:
a lens is employed to focus the laser light to the fast/slow axis as a beam;
said laser beam incident to a line lens along perpendicular to the fast axis to produce a line.

2. The method and apparatus for a laser line aligned to the fast axis of the laser source for fire rescue in claim 1 wherein:
a Powell lens is used for a line lens.

3. The method and apparatus for a laser line aligned to the fast axis of the laser source for fire rescue in claim 1 wherein:
a diffraction optical element is used for a line lens.
